(19) United States
(12) Patent Application Publication
(10) Pub. No.: US 2025/0004001 A1
(43) Pub. Date: Jan. 2, 2025

(54) SAMPLE MEASURING APPARATUS AND SAMPLE MEASURING METHOD

(71) Applicant: KONICA MINOLTA, INC., Tokyo (JP)

(72) Inventors: Takumi SAKURADA, Tokyo (JP); Yusuke MURAKAMI, Tokyo (JP); Katsunori TAKAHASHI, Tokyo (JP)

(73) Assignee: KONICA MINOLTA, INC., Tokyo (JP)

(21) Appl. No.: 18/746,061

(22) Filed: Jun. 18, 2024

(30) Foreign Application Priority Data
Jun. 29, 2023 (JP) 2023-106746

(51) Int. Cl. G01N 35/04; G01N 21/25; G01N 35/00

(52) U.S. Cl. CPC G01N 35/04; G01N 21/251; G01N 35/00584; G01N 35/0099

(57) ABSTRACT

A sample measuring apparatus is capable of surely assuring accuracy of aligning a sample. The sample measuring apparatus includes: a measuring device that measures a sample; a conveyance device that conveys the sample to a measurement section of the measuring device along a conveyance path; and a position assurance section into which the position assurance sample held by the conveyance device is fitted by driving of the conveyance device.

### CROSS-REFERENCE TO RELATED APPLICATION

The entire disclosure of Japanese patent Application No. 2023-106746, filed on Jun. 29, 2023, is incorporated herein by reference in its entirety.

### BACKGROUND OF THE INVENTION

### 1. Technical Field

The present invention relates to a sample measuring apparatus and a sample measuring method.

### 2. Description of Related art

As a technology related to alignment in conveyance using a conveyance device, there is a technology described in Japanese Unexamined Patent Application Publication No. 2019-115949. In this technology, while impedance control is performed in a first direction, an object gripped by an end effector of a robot is moved in a second direction different from the first direction. In this case, this technology is to detect whether or not a marker of the object and an identifying section of an inspection gauge have collided with each other, guide the marker of the object to the identifying section of the inspection gauge, and align the object.

### SUMMARY OF THE INVENTION

The technology described in Japanese Unexamined Patent Application Publication No. 2019-115949 is applied to determination of whether a processed portion in the object is good or not. The accuracy of aligning the object is assured only by the repeatability of the robot. However, the repeatability of the robot may degrade over time. Therefore, the accuracy of the alignment is not reliably assured.

Here, in a sample measuring apparatus in which a sample is measured by a measuring device, the sample held by a conveyance device needs to be accurately aligned and arranged with respect to a measurement section of the measuring device. Also in such a sample measuring apparatus, conventionally, the accuracy of aligning the sample is assured only by the repeatability of the conveyance device. Therefore, in a case where an error occurs in an inspection result, it is not possible to determine whether the error that occurred is caused by the sample or caused by the degradation of the repeatability of the conveyance device.

Therefore, an object of the present invention is to provide a sample measuring apparatus and a sample measuring method capable of reliably assuring the accuracy of aligning a sample.

To achieve the above-described object, according to the present invention, a sample measuring apparatus includes: a measuring device that measures a sample; a conveyance device that conveys the sample to a measurement section of the measuring device along a conveyance path; and a position assurance section into which a position assurance sample held by the conveyance device is fitted by driving of the conveyance device.

### BRIEF DESCRIPTION OF THE DRAWINGS

The advantages and features provided by one or more embodiments of the invention will become more fully understand from the detailed description given hereinbelow and the appended drawings which are given by way of illustration only, and thus are not intended as a definition of the limits of the present invention.

FIG. 1 is a schematic perspective view illustrating a configuration of a sample measuring apparatus according to a first embodiment;

FIG. 2 is a schematic plan view illustrating the configuration of the sample measuring apparatus according to the first embodiment;

FIG. 3 is a schematic perspective view illustrating a configuration of a cassette;

FIG. 4 is a schematic side view illustrating a configuration of a hand portion of a conveyance device;

FIG. 5 is a plan view illustrating a configuration of an alignment section;

FIG. 6 is a plan view illustrating a configuration of a position assurance section;

FIG. 7 is a side view illustrating a configuration of the position assurance section;

FIG. 8 is a plan view illustrating a second example of a position assurance sample;

FIG. 9 is a plan view illustrating a third example of the position assurance sample;

FIG. 10 is a flowchart illustrating a sample measuring method according to the first embodiment of the present invention;

FIG. 11 is a side view (part 1) of a main part illustrating a configuration of a sample measuring apparatus according to a second embodiment;

FIG. 12 is a plan view (part 1) of the main part illustrating the configuration of the sample measuring apparatus according to the second embodiment;

FIG. 13 is a side view (part 2) of the main part illustrating the configuration of the sample measuring apparatus according to the second embodiment;

FIG. 14 is a plan view (part 2) of the main part illustrating the configuration of the sample measuring apparatus according to the second embodiment;

FIG. 15 is a perspective view (part 1) of a main part illustrating a configuration of a sample measuring apparatus according to a third embodiment; and

FIG. 16 is a perspective view (part 2) of the main part illustrating the configuration of the sample measuring apparatus according to the third embodiment.

### DETAILED DESCRIPTION

Hereinafter, one or more embodiments of the present invention will be described with reference to the drawings. However, the scope of the invention is not limited to the disclosed embodiments.

In the embodiments, elements having substantially the same functions or configurations are denoted by the same reference signs, and redundant descriptions is omitted.

### First Embodiment

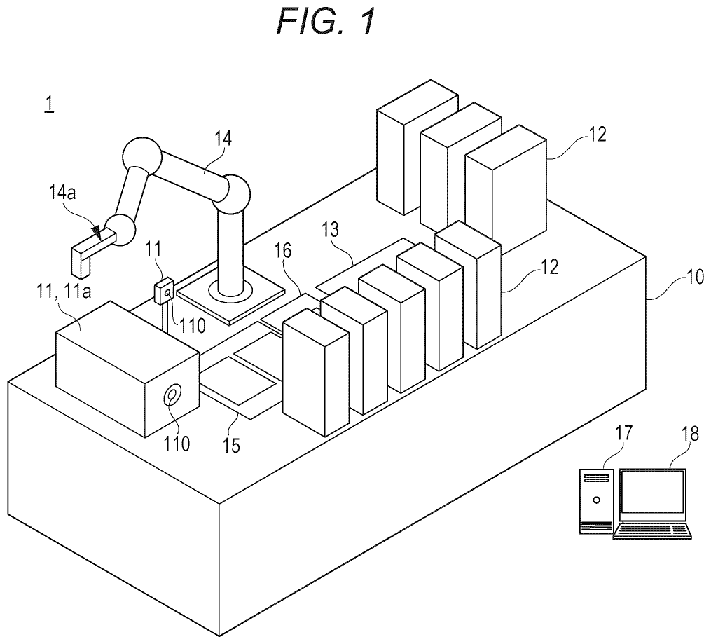

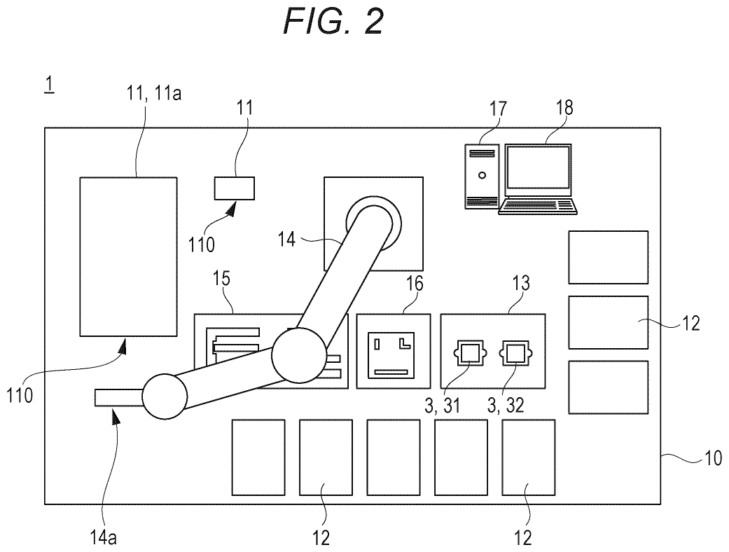

FIG. 1 is a schematic perspective view illustrating a configuration of a sample measuring apparatus according to a first embodiment of the present invention. FIG. 2 is a schematic plan view illustrating the configuration of the sample measuring apparatus according to the first embodiment of the present invention.

As illustrated in FIGS. 1 and 2, the sample measuring apparatus 1 includes a measuring device 11 that measures a sample (not illustrated). The measuring device 11 is installed on a base 10. On the base 10, a cassette 12, an alignment section 15, an assurance sample storage section 13, a position assurance section 16, and a conveyance device 14 are disposed. The sample measuring apparatus 1 further includes a controller 17 and an operation part 18. These parts will be described below.

### Measuring Device 11

The measuring device 11 measures the state of the sample. At least one measuring device 11 is disposed on the base 10. In the example illustrated in FIG. 1, a configuration in which two measuring devices 11 are provided is illustrated. Each of the measuring devices 11 includes a measurement section 110. Each of the measurement sections 110 measure the sample for a predetermined measurement item. For example, in a case where the measuring device 11 is a device that measures a surface condition of the sample, the measurement section 110 is a section that measures the surface condition of the sample. The surface condition of the sample includes the color, surface properties, temperature, and glossiness of the sample. The surface properties of the sample are typically the surface roughness of the sample.

At least one measuring device 11a among these measuring devices 11 is used for measuring an extremely narrow measurement region set on the sample. The measuring device 11a requires accurate alignment of the sample to be measured. In the present embodiment, the measuring device 11a is a device that measures the color of the sample, that is, a colorimeter. The sample to be measured is disposed in a state in which a non-measurement region set on a surface of the sample to be measured is close to and faces the measurement section 110 of the measuring device 11a.

### Cassette 12

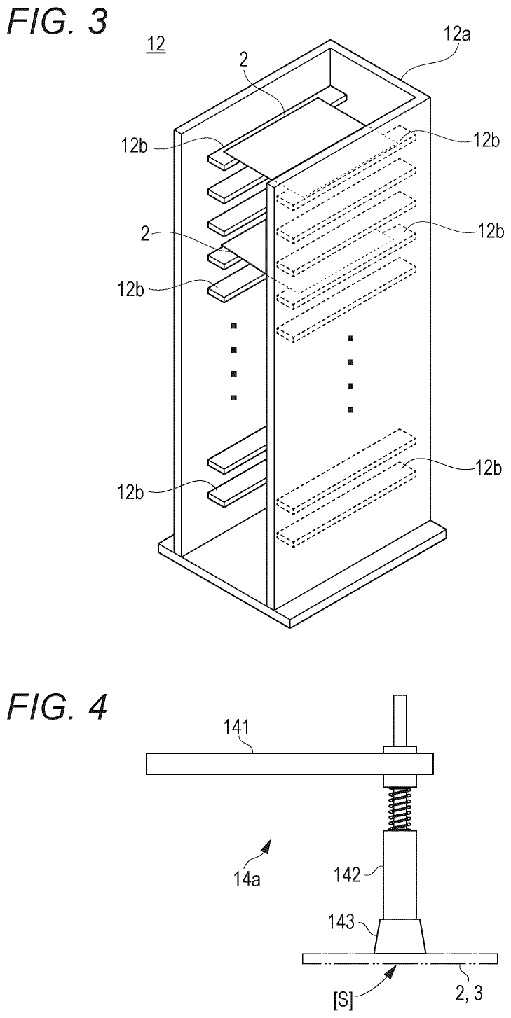

FIG. 3 is a schematic perspective view illustrating a configuration of the cassette 12. cassette 12 is used for storing a plurality of samples 2. Note that each of the samples 2 is typically a plate-like sample, more typically a flat plate-like sample. The plurality of samples 2 may have different planar shapes (i.e., shapes of surfaces to be measured) and different sizes.

The cassette 12 for storing the samples 2 includes a box-shaped housing 12a and support portions 12b for supporting the samples 2 in the housing 12a. The housing 12a has a configuration in which a top surface is opened so as not to interfere with (contact) a hand portion 14a of the conveyance device 14 described later. In addition, the housing 12a has a configuration in which a front surface is opened in order to horizontally load and unload a sample 2. The support portions 12b are provided in a state of protruding from a side circumferential surface of the housing 12a toward the vertical central axis of the housing 12a, and support the samples 2 in a horizontal posture. The support portions 12b are disposed in a plurality of stages at predetermined intervals in the height direction of the housing 12a. Note that the samples 2 are stored on the support portions 12b in the stages of the cassette 12 in a state where the surfaces to be measured face downward.

### Assurance Sample Storage Section 13

Returning to FIGS. 1 and 2, the assurance sample storage section 13 is a section for storing plate-like assurance samples 3. The assurance samples 3 (illustrated in FIG. 2 only) are a position assurance sample 31 and a color assurance sample 32. Each of these assurance samples 3 preferably has a shape that is the same as or similar to that of each of the samples 2, and is a flat plate-like sample.

Of these, the position assurance sample 31 is used for assuring the accuracy of aligning a sample by the conveyance device 14. In a case where the measuring device 11a is a colorimeter, the color assurance sample 32 is used to ensure that color detection by the colorimeter is accurately performed. It is preferable that these assurance samples 3 have a planar shape such that the assurance samples 3 can be aligned with high accuracy in the alignment section 15 described below.

The assurance sample storage section 13 has a portion on which the position assurance sample 31 and the color assurance sample 32 are individually placed in a predetermined state. Note that the assurance samples 3 are stored in the assurance sample storage section 13 while the surfaces to be measured are directed downward.

### Conveyance Device 14

The conveyance device 14 holds the sample 2 stored in the cassette 12 and the assurance samples 3 stored in the assurance sample storage section 13, and conveys the held sample 2 and assurance samples 3 along a predetermined route. The conveyance device 14 includes a multi-axis robot. In the present embodiment, as an example, the conveyance device 14 is constituted by a six-axis robot. The six-axis robot as the conveyance device 14 includes a force sensor (six-axis force sensor) (not illustrated). The conveyance device 14 includes the hand portion 14a for holding a sample. The hand portion 14a is disposed at a distal end portion of the six-axis robot constituting the conveyance device 14.

FIG. 4 is a schematic side view illustrating a configuration of the hand portion 14a of the conveyance device 14. As illustrated in FIG. 4, the hand portion 14a of the conveyance device 14 holds the sample 2 and the assurance samples 3 by, for example, vacuum suction. The hand portion 14a has a hand frame 141 extending from the distal end portion of the six-axis robot. A suction pad 143 is disposed at a tip of the hand frame 141 via a vacuum generator 142. The suction pad 143 is a cylindrical member made of rubber, and sucks one main surface of the sample 2 or any one of the assurance samples 3 by driving of the vacuum generator 142 to hold the sample 2 or the assurance sample 3. The suction pad 143 sucks the back surface of the sample 2 or the assurance sample 3 with respect to the surface [S] to be measured so as to hold the sample 2 or the assurance sample 3.

The conveyance device 14 including the hand portion 14a as described above holds and conveys the sample 2 and the assurance samples 3 along a predetermined route under control by the controller 17 described later.

### Alignment Section 15

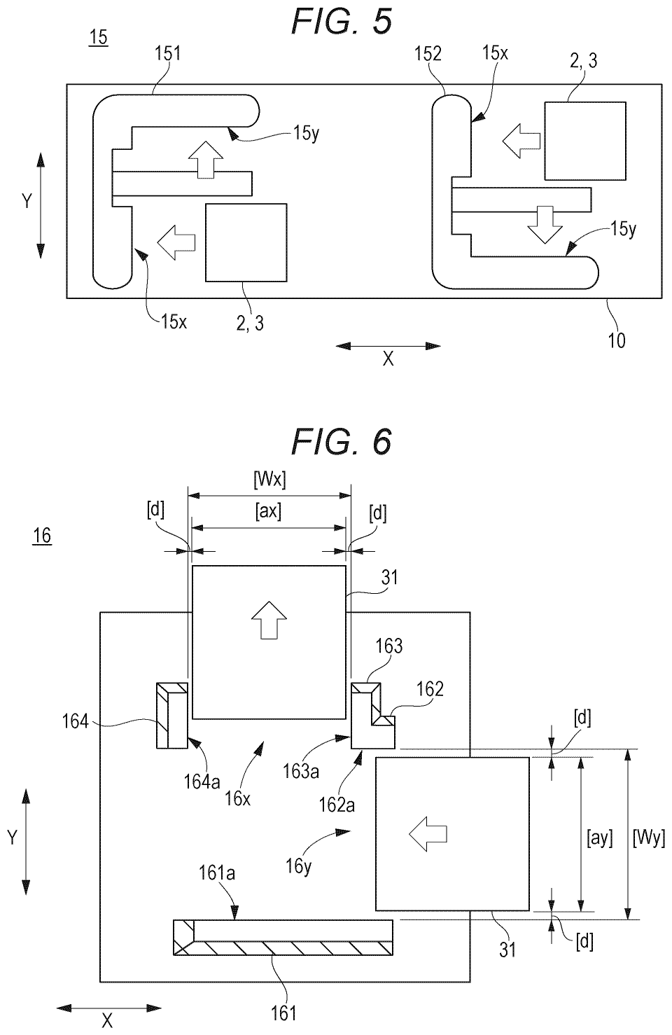

FIG. 5 is a plan view illustrating a configuration of the alignment section 15. The alignment section 15 illustrated in FIG. 5 is a section that aligns the sample 2 and the assurance samples 3. The alignment in this case is the determination of the postures and positions of the sample 2 and the assurance samples 3. The postures are defined by X, Y, and Z directions given to the sample 2 and the assurance samples 3. The positions are coordinate positions in the coordinate system of the sample measuring apparatus 1. This alignment is performed in order to hold the sample 2 and the assurance samples 3 in a predetermined state by the conveyance device 14.

The alignment section 15 includes a first alignment portion 151 and a second alignment portion 152. The first alignment portion 151 and the second alignment portion 152 are planar L-shaped members erected on the base 10. The second alignment portion 152 is disposed so as to be rotated by 90 degrees with respect to the first alignment portion 151 in the X-Y plane of the base 10.

Each of the first alignment portion 151 and the second alignment portion 152 includes an X end wall 15x and a Y end wall 15y. The X end wall 15x and the Y end wall 15y of each of the first alignment portion 151 and the second alignment portion 152 are vertical walls and form an included angle of 90° with each other.

In the alignment using the alignment portion 15, one of the first alignment portion 151 and the second alignment portion 152 is used according to the shapes of the sample 2 and the assurance samples 3. In this case, an end edge of the sample 2 or any one of the assurance samples 3 is brought into contact with the X end wall 15x and the Y end wall 15y. Thus, the postures and positions of the flat plate-like sample 2 and the assurance samples 3 are determined.

Here, the case where the planar shapes of the sample 2 and the assurance samples 3 are the illustrated square or rectangular shapes has been described, but the planar shapes of the sample 2 and the assurance samples 3 are not limited thereto. The planar shape of the sample 2 may be a triangle or another polygon, or may be a circle.

### Position Assurance Section 16

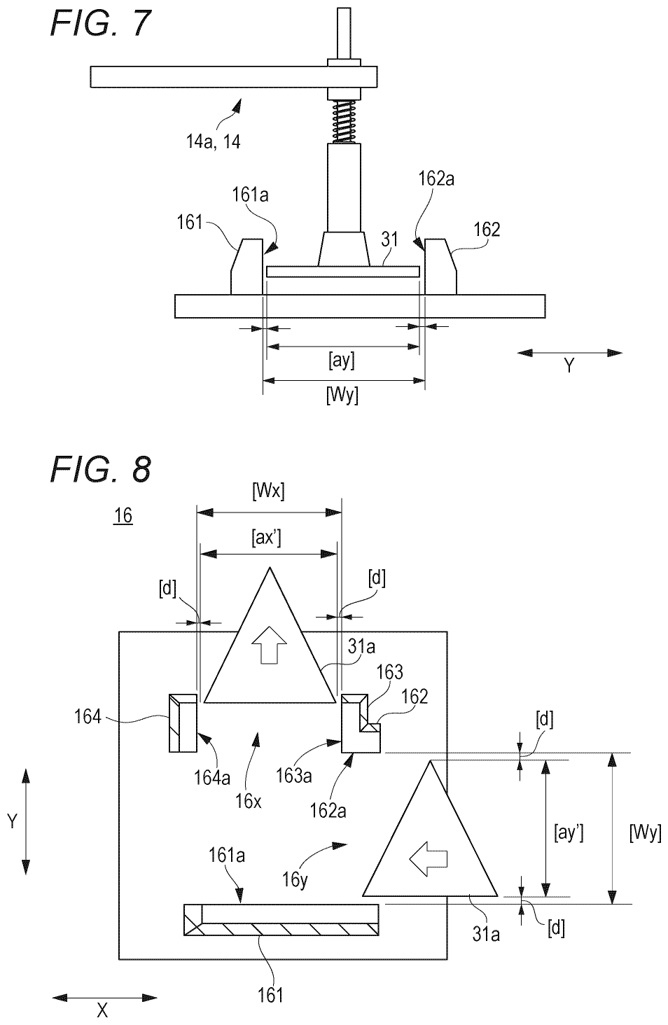

FIG. 6 is a plan view illustrating a configuration of the position assurance section 16. FIG. 7 is a side view illustrating the configuration of the position assurance section 16. The position assurance section 16 illustrated in FIGS. 6 and 7 is a section that performs position assurance using the position assurance sample 31. The position assurance sample 31 illustrated in FIGS. 6 and 7 is a first example of a position assurance sample. This position assurance is the assurance of the accuracy of aligning a sample. The position assurance includes the assurance of positions where the sample 2 and the assurance samples 3 are held by the conveyance device 14 and the assurance of a conveyance path. The conveyance device 14 fits the position assurance sample 31 held by the conveyance device 14 into the position assurance section 16. The conveyance device 14 fits the position assurance sample 31 into the position assurance section 16 in a non-contact manner and allows the position assurance sample 31 to pass through the position assurance section 16.

The position assurance section 16 includes first gate members 161 and 162 and second gate members 163 and 164 erected on an upper portion of the base 10. Note that X, Y, and Z directions given to the position assurance section 16 described below are the same as the X, Y, and Z directions given to the position assurance sample 31 in the alignment section 15 (see FIG. 5). The Z direction is given in consideration of the thickness of the position assurance sample 31 in order to keep a predetermined interval with respect to the floor surface of the position assurance section 16.

The first gate members 161 and 162 have X-direction vertical walls 161a and 162a extending in the X direction, respectively. These X-direction vertical walls 161a and 162a are arranged opposite to each other and constitute a first gate 16y opened in the Y-direction. The X-direction vertical walls 161a and 162a are disposed at a predetermined gate interval [Wy] in the Y direction. The gate interval [Wy] is set to be larger than the width [ay] of the position assurance sample 31 in the Y direction in plan view.

The first gate members 161 and 162 are disposed such that the position assurance sample 31 can be fitted into the position assurance section 16 from the X direction and can pass through the position assurance section 16. The position assurance sample 31 in this case is in a state where the posture of the position assurance sample 31 is matched with the X, Y, and Z directions of the position assurance section 16. Note that it is sufficient that the difference between the width [ay] of the position assurance sample 31 in the Y direction and the gate interval [Wy] of the first gate 16y is a value small enough to satisfy the positional accuracy required for the measurement at the measuring device 11a.

The second gate members 163 and 164 have Y-direction vertical walls 163a and 164a extending in the Y direction, respectively. These Y-direction vertical walls 163a and 164a are arranged opposite to each other and constitute a second gate 16x opened in the X-direction. The Y-direction vertical walls 163a and 164a are arranged at a predetermined gate interval [Wx] in the X direction. The gate interval [Wx] is set to be larger than the width [ax] of the position assurance sample 31 in the X direction in plan view.

The second gate members 163 and 164 are disposed such that the position assurance sample 31 can be fitted into the position assurance section 16 from the Y direction and can pass through the position assurance section 16. The position assurance sample 31 in this case is in a state where the posture of the position assurance sample 31 is matched with the X, Y, and Z directions of the position assurance section 16. Note that the difference between the width [ax] of the position assurance sample 31 in the X direction and the gate interval [Wx] of the second gate 16x may be a value small enough to satisfy the positional accuracy required for the measurement at the measuring device 11a.

The position assurance sample 31 passes through the first gate 16y and the second gate 16x of the position assurance section 16 by driving of the conveyance device 14. In the initial state, the conveyance path of the conveyance device 14 is set such that the position assurance sample 31 passes through the first gate 16y and the second gate 16x in a non-contact manner. In this case, gaps [d] between the first gate 16y and the second gate 16x and the position assurance sample 31 are equal. Thus, the conveyance path of the conveyance device 14 is preferably set such that the position assurance sample 31 passes through the centers of the first gate 16y and the second gate 16x.

Furthermore, in the initial state, the conveyance path of the conveyance device 14 is set such that the interval between the base 10 serving as a bottom surface and the position assurance sample 31 is a predetermined interval. The predetermined interval may be a value small enough to satisfy the positional accuracy required for the measurement at the measuring device 11a.

Note that FIG. 6 illustrates the case where the position assurance sample 31 has a rectangular shape, but the position assurance sample 31 is not limited thereto.

FIG. 8 is a plan view illustrating a position assurance sample 31a which is a second example of the position assurance sample. As illustrated in FIG. 8, the position assurance sample 31a may have a triangular planar shape. The coordinate position of the position assurance sample 31a having a triangular planar shape is determined, for example, in the above-described alignment section 15 (see FIG. 5) while the position assurance sample 31a is in an orientation in which one base of the triangle is parallel to the X direction. In this case, the gate interval [Wy] of the first gate 16y is larger than a distance [ay'] from the base of the position assurance sample 31a to the vertex of the position assurance sample 31a. Further, the gate interval [Wx] of the second gate 16x is larger than the length [ax'] of the base.

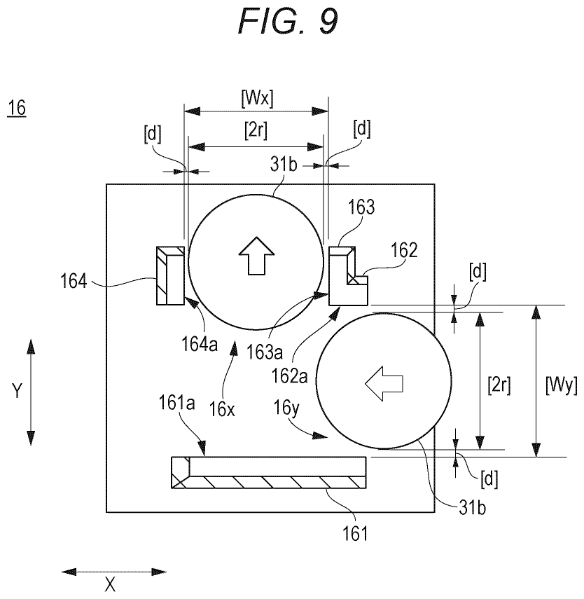

FIG. 9 is a plan view illustrating a position assurance sample 31b which is a third example of the position assurance sample. As illustrated in FIG. 9, the position assurance sample 31b may have a circular planar shape. When the circular position assurance sample 31b is used, the gate interval [Wy] of the first gate 16y and the gate interval [Wx] of the second gate 16x are larger than the diameter [2r] of the circle.

Note that FIG. 2 illustrates a state in which the position assurance section 16 is flatly installed on the base 10. However, the installation state of the position assurance section 16 is not limited thereto, and the position assurance section 16 may be installed vertically on the base 10.

### Controller 17

Referring back to FIGS. 1 and 2, the controller 17 includes, for example, a central processing unit (CPU), a read only memory (ROM), and a random access memory (RAM) as hardware resources of a computer. The CPU reads a predetermined program from the ROM, develops the program in the RAM, and executes the developed program, whereby the controller 17 comprehensively controls the operation of each part of the sample measuring apparatus 1.

The controller 17 controls a position assurance operation using the position assurance sample 31. Furthermore, the controller 17 controls a color measurement operation on the color assurance sample 32. Furthermore, the controller 17 controls a measurement operation on the sample 2 stored in the cassette 12. The control by the controller 17 will be described in detail in the following description of a sample measuring method.

### Operation Part 18

The operation part 18 includes a display part that displays various kinds of information to a user who uses the sample measuring apparatus 1. Furthermore, the operation part 18 includes an input part that accepts an input of various kinds of information from the user. The operation part 18 functions as a user interface.

The information input from the operation part 18 includes information regarding the sample 2 stored in the cassette 12 and information regarding the position assurance sample 31 and the color assurance sample 32 stored in the assurance sample storage section 13. The information regarding the sample 2 includes information indicating the type of sample 2, information indicating the size (including the shape) of the sample 2, information designating the cassette 12 in which the sample 2 is stored, and the like. Furthermore, the information regarding the position assurance sample 31 and the color assurance sample 32 includes information indicating the sizes (including the shapes) of the position assurance sample 31 and the color assurance sample 32 and information regarding positions where the position assurance sample 31 and the color assurance sample 32 are stored. These pieces of information are input by the user operating the operation part 18 before the start of the operation of the sample measuring apparatus described later.

The information input from the operation part 18 includes information of an instruction to start measurement and information of an instruction to start an assurance operation.

### Sample Measuring Method

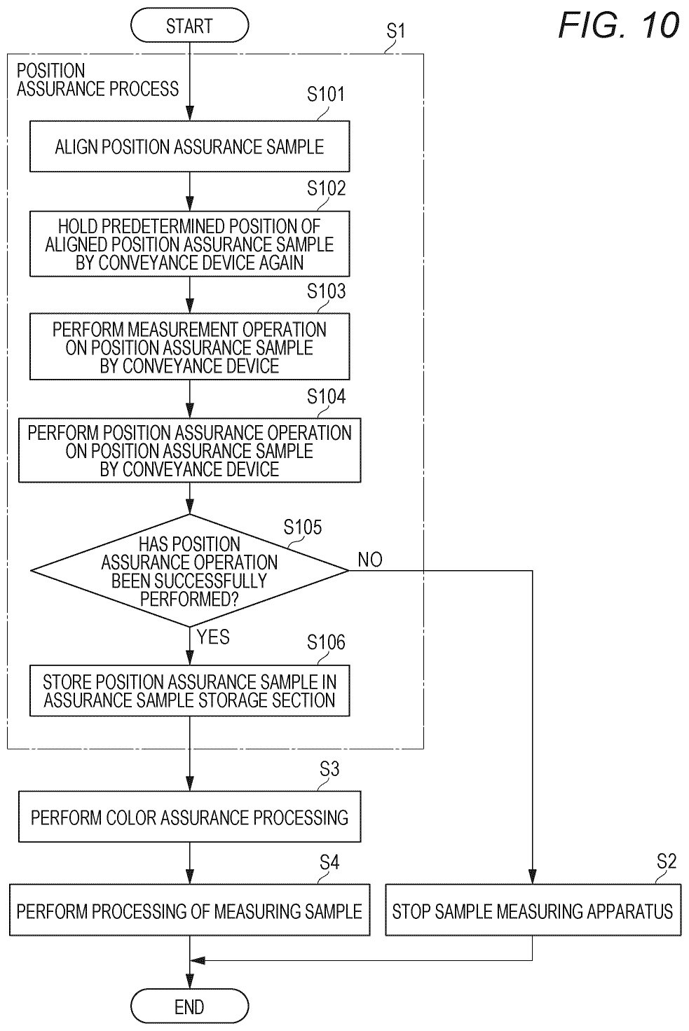

FIG. 10 is a flowchart illustrating the sample measuring method according to the first embodiment of the present invention. A procedure illustrated in this flowchart is implemented by a sample measurement program held in the controller 17 of the sample measuring apparatus 1 illustrated in FIG. 1. Hereinafter, the sample measuring method according to the first embodiment will be described with reference to FIGS. 1 to 9 previously illustrated, according to the procedure illustrated in FIG. 10.

### —Step S1—

In step S1, the controller 17 performs a position assurance process in a procedure of the following steps S101 to S106.

### [Step S101]

In step S101, the controller 17 controls the driving of the conveyance device 14 to align the position assurance sample 31. In this case, first, the conveyance device 14 holds the position assurance sample 31 stored in the assurance sample storage section 13 in a predetermined state, and conveys the position assurance sample 31 to the alignment section 15. The conveyance device 14 aligns the position assurance sample 31 in a predetermined procedure in any one of the first alignment section 151 and the second alignment section 152 set in advance, and determines the posture and the position of the position assurance sample 31.

### [Step S102]

In step S102, the controller 17 causes the hand portion 14a to hold a predetermined position of the aligned position assurance sample 31 again by driving the conveyance device 14. In this case, the conveyance device 14 moves the hand portion 14a to a coordinate position (predetermined position) set in advance based on size information of the position assurance sample 31, and holds the position assurance sample 31 again.

The coordinate position set in advance is the center position of the position assurance sample 31 aligned in the alignment section 15.

### [Step S103]

In step S103, the controller 17 drives the conveyance device 14 to perform a measurement operation on the position assurance sample 31. In this case, the conveyance device 14 conveys the position assurance sample 31 held by the hand portion 14a to the measuring device 11. The conveyance device 14 sequentially arranges the position assurance sample 31 such that a surface of the position assurance sample 31 to be measured faces the measurement section 110 of each measuring device 11. The surface to be measured is opposite to a surface of the position assurance sample 31 held by the hand portion 14a of the conveyance device 14. Note that in this measurement operation, it is sufficient to perform only the conveyance of the position assurance sample 31 by the conveyance device 14, and it is not necessary to perform the measurement by each measuring device 11.

### [Step S104]

In step S104, the controller 17 drives the conveyance device 14 to perform the position assurance operation using the position assurance sample 31. In this case, the conveyance device 14 conveys the held position assurance sample 31 to the position assurance section 16. The conveyance device 14 keeps the position assurance sample 31 in a predetermined state. The predetermined state is a state in which the orientation of the position assurance sample 31 in the X and Y directions is aligned with the orientation of the position assurance section 16 in the X and Y directions.

In this state, the conveyance device 14 fits the position assurance sample 31 into the first gate 16y of the position assurance section 16 from the X direction. Next, the conveyance device 14 conveys the held position assurance sample 31 in the X direction such that the position assurance sample 31 passes through the first gate 16y. Furthermore, the conveyance device 14 fits the position assurance sample 31 into the second gate 16x of the position assurance section 16 from the Y direction. Then, the conveyance device 14 conveys the held position assurance sample 31 in the Y direction such that the position assurance sample 31 passes through the second gate 16x. During the time when the position assurance sample 31 passes through the first gate 16y and the second gate 16x, the position assurance sample 31 is held at a predetermined distance from the bottom surfaces of the first gate 16y and the second gate 16x.

### [Step S105]

In step S105, the controller 17 determines whether or not the position assurance operation using the position assurance sample 31 has been successfully performed. The controller 17 makes this determination based on a signal from the force sensor of the conveyance device 14. In a case where the controller 17 does not detect a signal indicating that the position assurance sample 31 has contacted a structure such as the first gate 16y or the second gate 16x during the position assurance operation in step S104, the controller 17 determines that the position assurance has been successful (YES). In this case, the process proceeds to step S106. On the other hand, in a case where the controller 17 detects the signal indicating that the position assurance sample 31 has contacted the structure during the position assurance operation in step S104, the controller 17 determines that position assurance has failed (NO). In this case, the process proceeds to step S2.

### —Step S2—

In step S2, the controller 17 stops the sample measuring apparatus 1. In this case, the controller 17 transmits the result of the determination in step S105 to the operation part 18. The operation part 18 provides a notification indicating that the position assurance has failed by display or sound.

### [Step S106]

On the other hand, in step S106, the controller 17 stores the position assurance sample 31 in the assurance sample storage section 13 by driving the conveyance device 14. In this case, the conveyance device 14 places the position assurance sample 31 in the assurance sample storage section 13 in a predetermined state.

### —Step S3—

In step S3, the controller 17 performs color assurance processing. In this case, the controller 17 drives the conveyance device 14 to align the color assurance sample 32. This alignment operation is the same as or similar to the operation performed in step S101. Next, the controller 17 causes the hand portion 14a to hold the center position of the aligned color assurance sample 32 by driving the conveyance device 14. This operation is the same as or similar to the operation described in step S102. Thereafter, the controller 17 measures the color assurance sample 32 by driving the conveyance device 14. This measurement operation is the same as or similar to the operation performed in step S103. However, in this measurement operation, the conveyance of the color assurance sample 32 by the conveyance device 14 and the measurement of the color assurance sample 32 by each measuring device 11 are performed. Furthermore, the controller 17 transmits results of the measurement to the operation part 18.

### —Step S4—

In step S4, the controller 17 performs processing of measuring the sample. In this case, the controller 17 takes out the sample 2 from the cassette 12 and aligns the taken-out sample 2 by driving the conveyance device 14. This alignment operation is the same as or similar to the operation performed in step S101. Next, the controller 17 causes the hand portion 14a to hold the center position of the aligned sample 2 by driving the conveyance device 14. This operation is the same as or similar to the operation described in step S102. Thereafter, the controller 17 measures the sample 2 by driving the conveyance device 14. This measurement operation is the same as or similar to the operation performed in step S103. However, in the measurement operation, the conveyance of the sample 2 by the conveyance device 14 and the measurement of the sample 2 by each measuring device 11 are performed. Thereafter, the controller 17 drives the conveyance device 14 to store the sample 2 in a different cassette 12. The different cassette 12 is a cassette 12 different from the cassette 12 from which the measured sample 2 has been taken out.

This step S4 is repeated for a plurality of samples 2 in a preset order. When the measurement processing for the set plurality of samples 2 is completed, the procedure of the sample measurement is completed.

Furthermore, the sample measuring method according to the present invention is not limited to the order illustrated in the flowchart of FIG. 10. For example, a configuration may be adopted in which the processing from step SI to step S4 is repeated every time the processing of measuring a preset number of samples 2 in step S4 is completed. Further, after the processing of measuring the sample is performed, the position assurance process (step S1) and the color assurance processing (step S3) may be performed.

### Effects of First Embodiment

In the first embodiment described above, the conveyance device 14 conveys the position assurance sample 31 such that the position assurance sample 31 is fitted into the position assurance section 16, and thus the position where the position assurance sample 31 is held by the conveyance device 14 and the movement route of the position assurance sample 31 are assured with high accuracy. Therefore, it is possible to assure the accuracy of aligning the sample conveyed to the measuring device 11 by the conveyance device 14.

As a result, for example, the sample 2 can be measured in a state in which the predetermined position reliably corresponds to the measurement section 110 of the measuring device 11a. Therefore, highly accurate measurement can be performed. Furthermore, in a case where an error occurs in the measurement result, it can be determined that the error is not caused by the degradation of the conveyance device 14 or the alignment section 15 over time, and the cause of the error can be isolated.

The position assurance operation is performed after the measurement operation using the position assurance sample 31. Thus, for example, when a failure occurs in the conveyance device 14 in the measurement operation, the occurrence of the failure can be detected in the position assurance operation. Therefore, the accuracy of aligning the sample can be assured through all the operations from the alignment in the alignment section 15 to the measurement at the measuring device 11a.

### Second Embodiment

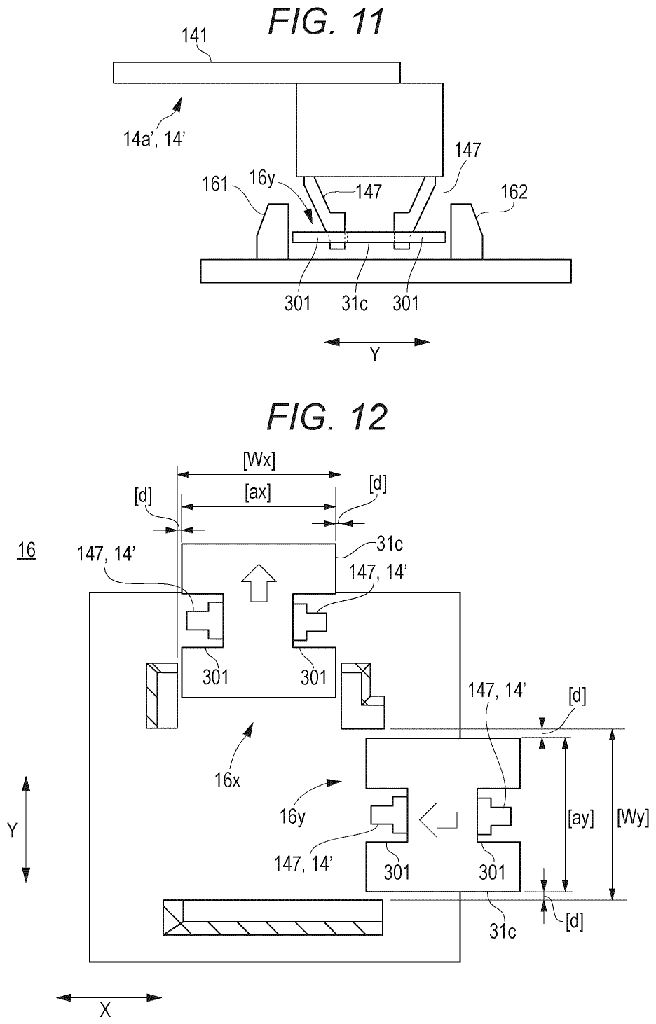

FIG. 11 is a side view (part 1) of a main part illustrating a configuration of a sample measuring apparatus according to the second embodiment. FIG. 12 is a plan view (part 1) of the main part illustrating the configuration of the sample measuring apparatus according to the second embodiment. As illustrated in these drawings, a hand portion 14a′ of a conveyance device 14′ included in the sample measuring apparatus may be configured to hold a sample or an assurance sample by gripping. The hand portion 14a′ has gripping claws 147 at tips of a hand frame 141 extending from a tip part of the six-axis robot. The number of the gripping claws 147 may be two, or may be three or more. Note that two gripping claws 147 are illustrated in the drawings. These gripping claws 147 grip the sample or the assurance sample between the plurality of gripping claws 147 by bringing distal ends of the gripping claws 147 close to each other.

In this case, a position assurance sample 31c illustrated in FIGS. 11 and 12 has a configuration such that the gripping claws 147 gripping the position assurance sample 31c do not protrude from the outer periphery of the position assurance sample 31c. The position assurance sample 31c illustrated in FIGS. 11 and 12 is a fourth example of a position assurance sample. In one example, the position assurance sample 31c includes a plurality of recessed portions 301 in its outer peripheral edge. The recessed portions 301 are arranged corresponding to the gripping claws 147 of the hand portion 14a′. The conveyance device 14′ grips the position assurance sample 31c by bringing the distal ends of the gripping claws 147 inserted in the respective recessed portions 301 of the position assurance sample 31c close to each other.

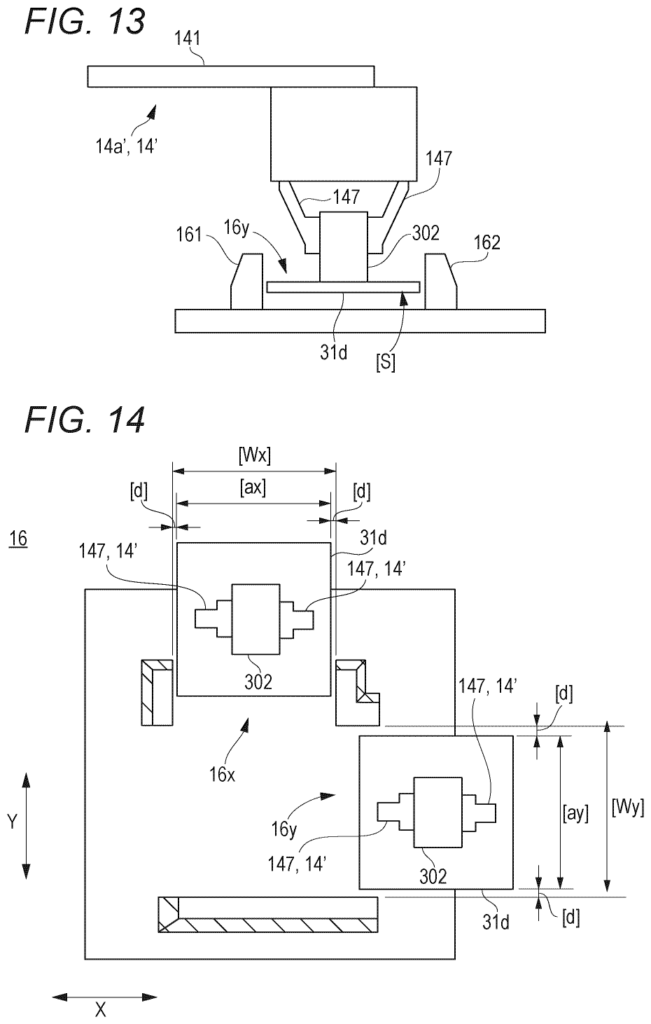

FIG. 13 is a side view (part 2) of the main part illustrating the configuration of the sample measuring apparatus according to the second embodiment. FIG. 14 is a plan view (part 2) of the main part illustrating the configuration of the sample measuring apparatus according to the second embodiment. As illustrated in these drawings, a position assurance sample 31d may have a configuration such that a gripped portion 302 is attached to the back surface of the position assurance sample 31d with respect to a surface to be measured [S]. The gripped portion 302 has a shape such that the gripped portion 302 can be gripped by the gripping claws 147 of the hand portion 14a′. The position assurance sample 31d illustrated in FIGS. 13 and 14 is a fifth example of a position assurance sample. The conveyance device 14′ holds the position assurance sample 31d by gripping the gripped portion 302 of the position assurance sample 31d. The gripped portion 302 is attached to the position assurance sample 31d such that the gripping claws 147 gripping the position assurance sample 31d do not protrude from the outer periphery of the position assurance sample 31d.

### Effects of Second Embodiment

As described above, even in a case where the hand portion 14a′ of the conveyance device 14′ has the gripping claws 147, the position assurance operation described in the first embodiment can be performed by providing the recessed portions 301 (refer to FIG. 12) and the gripped portion 302 (refer to FIG. 13) in the position assurance sample 31. The position assurance operation is the position assurance operation of step S104 in FIG. 10. Therefore, the same effects as those of the first embodiment are obtained.

### Third Embodiment

FIG. 15 is a perspective view (part 1) of a main part illustrating a configuration of a sample measuring apparatus according to a third embodiment, and is a plan view illustrating another example of the position assurance section described in the first embodiment. A position assurance section 16′ illustrated in FIG. 15 has one gate opening 16a. When the position assurance sample 31 is moved in one direction, the position assurance sample 31 is fitted into the gate opening 16a in two directions perpendicular to the movement direction. The gate opening 16a has, for example, a similar shape to a planar shape of the plate-shaped position assurance sample 31. The gate opening 16a is an opening through which the position assurance sample 31 moved in the one direction can pass.

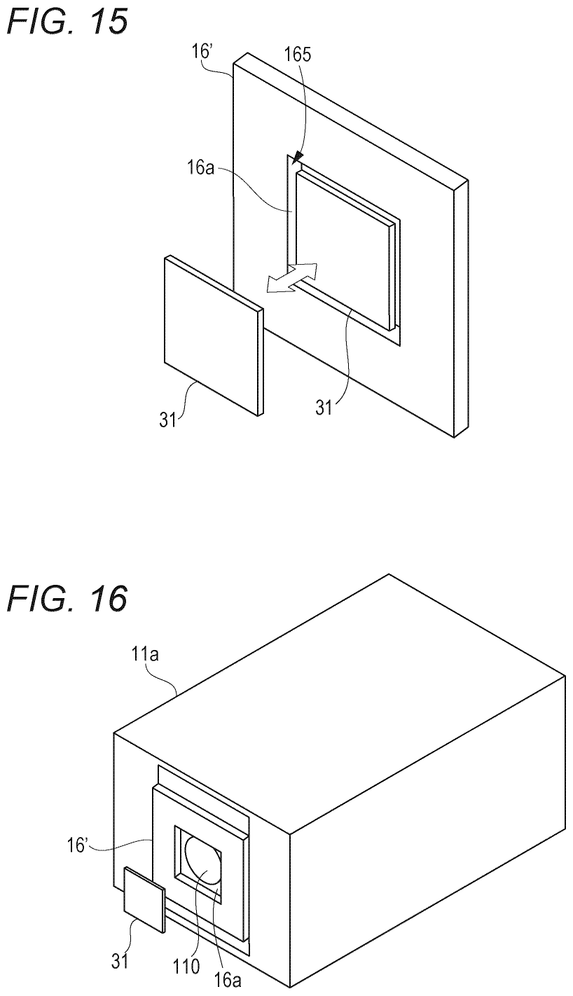

FIG. 16 is a perspective view (part 2) of the main part illustrating the configuration of the sample measuring apparatus according to the third embodiment. As illustrated in FIG. 16, the position assurance section 16′ may be disposed such that the gate opening 16a faces a measurement section 110 of a measuring device 11a. The measuring device 11a is a component that requires accuracy in alignment of a sample relative to the measurement section 110. In this case, the planar shapes of the position assurance sample 31 and the gate opening 16a are made sufficiently larger than the planar shape of sample (not illustrated) to be measured.

### Effects of Third Embodiment

Even with the configuration of the third embodiment, the same effects as those of the first embodiment can be obtained. In addition, in a case where the position assurance section 16′ according to the third embodiment is disposed to face the measurement section 110 of the measuring device 11a, the measurement operation and the position assurance operation using the position assurance sample 31 can be performed at the same time. The measurement operation is the measurement operation in step S103 in FIG. 10. The position assurance operation is the position assurance operation in step S104 in FIG. 10.

Note that the above-described embodiments have been described in detail in order to explain the present invention in an easy-to-understand manner, but the present invention is not limited to the above-described embodiments and modification examples. For example, the alignment of the sample 2 may be performed in the cassette 12. In this case, it is sufficient to provide the assurance sample storage section 13 with an alignment function, and it is not necessary to provide the alignment section 15.

Although embodiments of the present invention have been described and illustrated in detail, the disclosed embodiments are made for purposes of illustration and example only and not limitation. The scope of the present invention should be interpreted by terms of the appended claims.

What is claimed is:

1. A sample measuring apparatus comprising:
a measuring device that measures a sample;
a conveyance device that conveys the sample to a measurement section of the measuring device along a conveyance path; and
a position assurance section into which the position assurance sample held by the conveyance device is fitted by driving of the conveyance device.

2. The sample measuring apparatus according to claim 1, further comprising an alignment section in which the position assurance sample is aligned in a predetermined position and posture, wherein the conveyance device fits the position assurance sample aligned in the alignment section into the position assurance section.

3. The sample measuring apparatus according to claim 1, wherein the position assurance sample is fitted into the position assurance section in two perpendicular directions set for the position assurance sample.

4. The sample measuring apparatus according to claim 3, wherein
the position assurance section includes a plurality of gate members erected on a bottom surface,
the plurality of gate members include vertical walls arranged opposite to each other, and
the conveyance device fits the position assurance sample into the position assurance section between the vertical walls of the gate members and allows the position assurance sample to further pass through the position assurance section.

5. The sample measuring apparatus according to claim 4, wherein the conveyance device maintains a predetermined interval between the position assurance sample and the bottom surface between the vertical walls of the gate members.

6. The sample measuring apparatus according to claim 3, wherein
the position assurance section has a gate opening into which the position assurance sample is fitted, and
the conveyance device fits the position assurance sample into the gate opening of the position assurance section by conveying the position assurance sample in one direction perpendicular to the two directions.

7. The sample measuring apparatus according to claim 6, wherein the position assurance section is disposed such that the gate opening of the position assurance section faces a measurement section of the measuring device.

8. The sample measuring apparatus according to claim 1, wherein the position assurance sample is fitted into the position assurance section in a non-contact manner.

9. The sample measuring apparatus according to claim 1, further comprising a controller that controls the conveyance device, wherein
the conveyance device includes a force sensor, and
the controller stops the driving of the conveyance device when the controller determines, based on a signal from the force sensor, that the position assurance sample is not fitted into the position assurance section.

10. The sample measuring apparatus according to claim 9, wherein the controller conveys the position assurance sample to the measuring device and then fits the position assurance sample into the position assurance section.

11. The sample measuring apparatus according to claim 10, wherein the controller controls the conveyance device such that the conveyance device conveys the position assurance sample to the measuring device and a predetermined position of the position assurance sample coincides with a measurement position of the measuring device.

12. The sample measuring apparatus according to claim 11, wherein the conveyance device holds a predetermined position of the position assurance sample based on size information of the position assurance sample.

13. The sample measuring apparatus according to claim 1, further comprising a controller that controls the conveyance device, wherein the controller causes the position assurance sample to be fitted into the position assurance section before or after a job of measurement of the sample by the measuring device is started or every time measurement of a predetermined number of samples is performed.

14. The sample measuring apparatus according to claim 1, wherein the conveyance device includes a hand portion that holds the sample and the position assurance sample by suction.

15. The sample measuring apparatus according to claim 1, wherein the measuring device measures a surface condition of the sample.

16. The sample measuring apparatus according to claim 15, wherein the surface condition of the sample is at least one of color, surface properties, and glossiness of the sample.

17. A sample measuring method by a sample measuring apparatus including a measuring device that measures a sample and a conveyance device that conveys the sample to a measurement section of the measuring device along a conveyance path, the sample measuring method comprising:
causing a controller to fit a position assurance sample held by the conveyance device into a position assurance section by driving the conveyance device such that positional accuracy in conveyance by the conveyance device is assured.

18. The sample measuring method according to claim 17, wherein the controller aligns the position assurance sample in a predetermined position and posture in an alignment section and then fits the position assurance sample into the position assurance section.

19. The sample measuring method according to claim 18, wherein the controller conveys the aligned position assurance sample to the measuring device and then fits the position assurance sample into the position assurance section.
